(19) United States
(12) Patent Application Publication
(10) Pub. No.: US 2021/0152905 A1
(43) Pub. Date: May 20, 2021

(54) ONE-TO-MANY WIRELESS SPEAKER SOUND BOX DEVICE

(71) Applicant: UDID TECHNOLOGY CO., LTD., New Taipei City (TW)

(72) Inventor: Liang-Tan TSAI, New Taipei City (TW)

(21) Appl. No.: 16/683,598

(22) Filed: Nov. 14, 2019

(51) Int. Cl. H04R 1/02; H04R 3/12; H04R 5/02; H04R 5/04; H04R 7/16; H04S 7/00; H03F 3/217; H03F 3/68; H04W 4/80

(52) U.S. Cl. CPC H04R 1/025; H04R 3/12; H04R 5/02; H04R 5/04; H04R 7/16; H04S 2400/01; H03F 3/217; H03F 3/68; H04W 4/80; H04R 2201/028; H04R 2420/07; H04S 7/30

(57) ABSTRACT

A one-to-many wireless speaker sound box device is disclosed, which is an integrally formed device and comprises an outer case, one or more diaphragm components, at lease two speaker bodies and at least one electric circuit board, wherein the electric circuit board includes a wireless transmission unit, a digital audio signal processing unit and at least two D-typed amplifier units, and the one-to-many wireless speaker sound box device is able to generate at least two or more sound channels, and each of the D-typed amplifier units is able to combine the left and right sound channel outputs in parallel into a single sound channel output and amplify the output audio signal in multiplication thereby driving the speaker bodies corresponding to different sound channels to operate, so that the issue “the higher the power is, the larger the magnification becomes, but the increased signal distortion ratio will also occur” typically found in the D-typed amplifier units can be resolved, and the effect of acoustic perception efficiency multiplication can be also achieved. Moreover, in addition to being applied to play music as a single one-to-many wireless speaker sound box device, two or more one-to-many wireless speaker sound box devices according to the present invention can be further connected in groups to play/receive audio signals thus generating the effects of music playing and karaoke singing entertainment.

### BACKGROUND OF THE INVENTION

### 1. Field of the Invention

The present invention generally relates to a one-to-many wireless speaker sound box device; in particular, it relates to a one-to-many wireless speaker sound box device capable of improving the issue that the signal distortion of the D-typed power amplifier becomes excessively large.

### 2. Description of Related Art

Power amplifiers play an important role in the design of integrated circuits. They are comprehensively used in various transmitters and receivers of public broadcasting apparatuses, stereo devices, microcomputers as well as other electric equipments or the like. The function of the power amplifier is essentially to increase the signal energy in order to drive the speaker body load or the circuits in the next stage.

It is well-known that the power amplifiers include various classifications depending on their applications and purposes, mainly type A, type B, type AB, type C and type D. Among them, D-typed power amplifiers enable high power conversion efficiency (greater than 90%) and is widely used because of its low cost. However, for products requiring higher signal-to-distortion ratios and signal-to-noise ratios, D-typed power amplifiers do not perform so satisfactorily as AB-typed power amplifiers.

Especially, when the input signal is large enough to a certain extent (usually about half of the reference level), the Total Harmonic Distortion plus Noise (THD+N) of the D-typed power amplifier will increase sharply, in which the THD+N is defined as the ratio of the sum of the distortion harmonic power and the noise generated by the device itself to its output power.

Therefore, if the D-typed power amplifier is applied to multi-channel wireless speakers, this problem may become more serious because each amplifier uses the output of more than two channels. As such, the design of the present invention uses a single D-typed amplifier unit to drive only a single channel output connected to more than one speaker bodies, thereby resolving the issue of excessively large signal distortion commonly found in such power amplifiers. Accordingly, the present invention allows an optimal solution with high power, low distortion ratio and reduced costs.

### SUMMARY OF THE INVENTION

A one-to-many wireless speaker sound box device according to the present invention is disclosed, comprising: an outer case, including multiple inner wall surfaces which together form an accommodation space; one or more diaphragm components which include an outer support frame and a diaphragm body, wherein the diaphragm body is bonded to one side of the outer support frame, and the other side of the outer support frame is fixed to the Inner wall surfaces, and also the diaphragm body can replace any effects generated by conventional passive monomers or the sound tubes and reduce the external size and internal volume of the sound box; at least two speaker bodies, which are disposed in the accommodation space, with each speaker body being used to play sounds of different channels; at least one electric circuit board, which is electrically connected to the speaker body and disposed in the accommodation space, in which the electric circuit board thereon includes: a wireless transmission unit, used for receiving an input audio in a wireless transmission manner; a digital audio signal processing unit, electrically connected to the wireless transmission unit for performing signal processing on the input audio in order to generate a virtual sound field signal; and at least two D-typed amplifier units, electrically connected to the sound output conversion unit, with each D-typed amplifier unit being connected to one or more speaker bodies in correspondence with a single channel respectively, thereby receiving the virtual sound field signal through each D-typed amplifier unit and converting to obtain an output audio which is then amplified in multiple times so as to drive a single channel and one or more speaker body outputs, thus creating the multi-channel playback effect.

More specifically, the wireless transmission mode of the wireless transmission unit is Bluetooth™ or Wi-Fi.

More specifically, the one-to-many wireless speaker sound box device is integrally manufactured in one piece.

More specifically, the multi-channel can be of 2.0 channels, 2.1 channels, 5.1 channels, or 5.1 channels or more.

More specifically, it is further possible to transfer the input audio signals into the one-to-many wireless speaker sound box device by way of at least one transmission line.

More specifically, a sound output conversion unit can be further connected between the digital audio signal processing unit and the D-typed amplifier unit in order to receive the virtual sound field signal and convert into the virtual sound field signal of multiple sound channels.

More specifically, the digital audio signal processing unit performs signal processes on the input audio signal so as to generate the virtual sound field signal of multiple sound channels.

More specifically, each of the D-typed amplifier units is able to output two or more sound channels, and to combine the left and right sound channel outputs in parallel into a single sound channel output.

More specifically, in addition to being applied to play music as a single one-to-many wireless speaker sound box device, it is further possible to connect two or more one-to-many wireless speaker sound box devices in groups to play/receive audio signals in order to generate the effects of music playing and karaoke singing.

More specifically, with the one-to-many wireless speaker sound box device according to the present invention, the issue “the higher the power is, the larger the magnification becomes, but the increased signal distortion ratio will also occur” typically found in the D-typed amplifier units can be resolved.

More specifically, the diaphragm body is made of soft or elastic materials.

More specifically, the outer case includes at least one through hole which penetrates to the inner wall surface, and the diaphragm component covers the through hole on the inner wall surface.

### BRIEF DESCRIPTION OF THE DRAWINGS

FIG. 1A shows a structural view for a first embodiment of the one-to-many wireless speaker sound box device according to the present invention.

FIG. 1B shows a cross-sectioned structural view on one side for the first embodiment of the one-to-many wireless speaker sound box device according to the present invention.

FIG. 1C shows a cross-sectioned structural view on the other side for the first embodiment of the one-to-many wireless speaker sound box device according to the present invention.

FIG. 2A shows a structural view for a second embodiment of the one-to-many wireless speaker sound box device according to the present invention.

FIG. 2B shows a cross-sectioned structural view on one side for the second embodiment of the one-to-many wireless speaker sound box device according to the present invention.

FIG. 2C shows a cross-sectioned structural view on the other side for the second embodiment of the one-to-many wireless speaker sound box device according to the present invention.

FIG. 3 shows an architectural view for the electric circuit board in the one-to-many wireless speaker sound box device according to the present invention.

FIG. 4 shows an architectural view for a first application embodiment of the electric circuit board in the one-to-many wireless speaker sound box device according to the present invention.

FIG. 5 shows an architectural view for a second application embodiment of the electric circuit board in the one-to-many wireless speaker sound box device according to the present invention.

FIG. 6 shows an architectural view for a third application embodiment of the electric circuit board in the one-to-many wireless speaker sound box device according to the present invention.

FIG. 7 shows an architectural view for a third application embodiment of the electric circuit board in the one-to-many wireless speaker sound box device according to the present invention.

### DETAILED DESCRIPTION OF THE PREFERRED EMBODIMENTS

Other technical contents, aspects and effects in relation to the present invention can be clearly appreciated through the detailed descriptions concerning the preferred embodiments of the present invention in conjunction with the appended drawings.

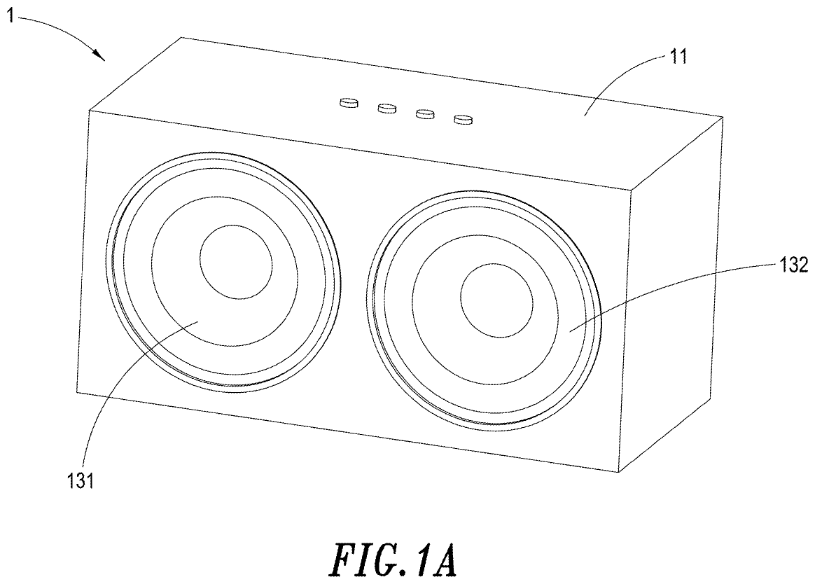

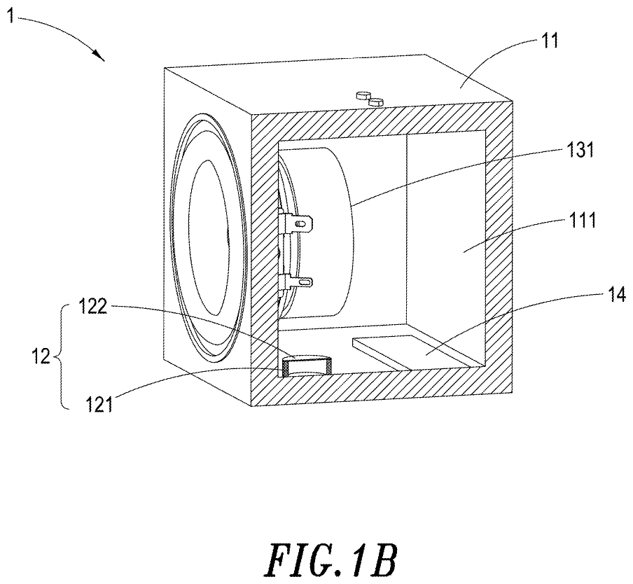

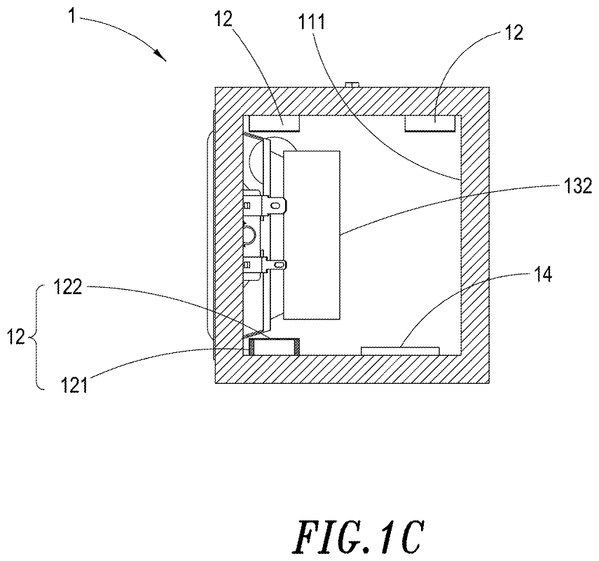

Initially, refer to FIGS. 1A-1C, wherein a structural view for a first embodiment, a cross-sectioned structural view on one side for the first embodiment and a cross-sectioned structural view on the other side for the first embodiment of the one-to-many wireless speaker sound box device according to the present invention are respectively shown. It should be understood that the one-to-many wireless speaker sound box device can be integrally manufactured in one piece. The illustrated one-to-many wireless speaker sound box device 1 comprises an outer case 11 which includes several inner wall surfaces 111 such that these inner wall surfaces 111 together form an accommodation space; also, plural diaphragm components 12 can be further combined onto these inner wall surfaces 111 and include an outer support frame 121 and a diaphragm body 122, wherein the diaphragm body 122 is bonded to one side of the outer support frame 121, and the other side of the outer support frame 121 is fixed to the Inner wall surface 111. Additionally, the diaphragm body 122 can be manufactured by means of soft or elastic materials.

Herein the accommodation space is further configured with at least two speaker bodies 131, 132 and at least one electric circuit board 14, in which the two speaker bodies 131, 132 can be fixed onto the inner wall surface 111 and protrude outwards to reveal a sound generating plane, with each of these speaker bodies 131, 132 operating to play sound from different channels.

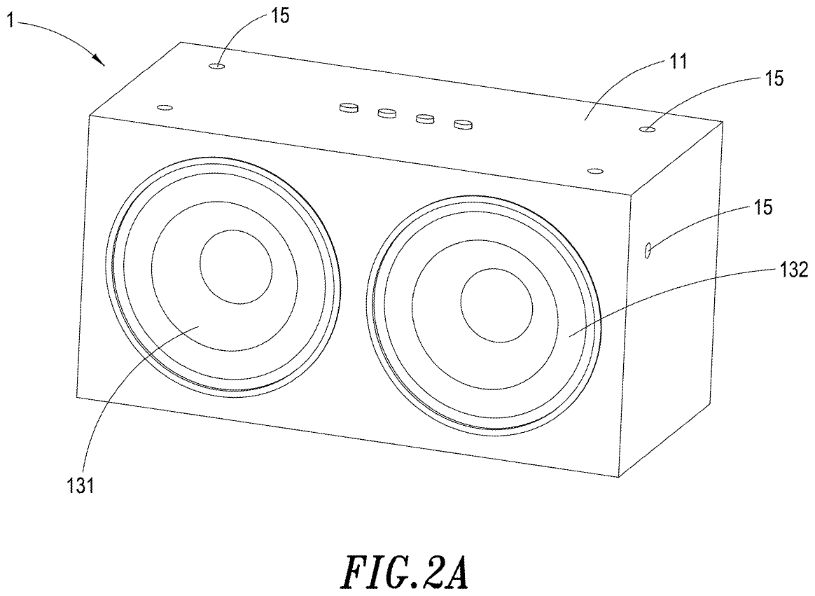

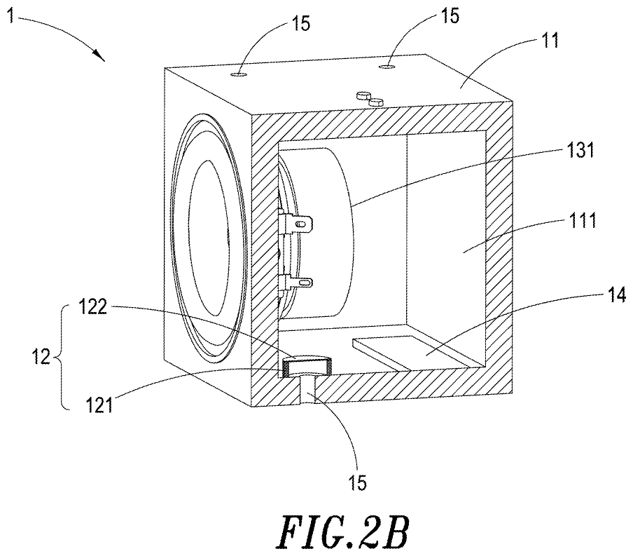

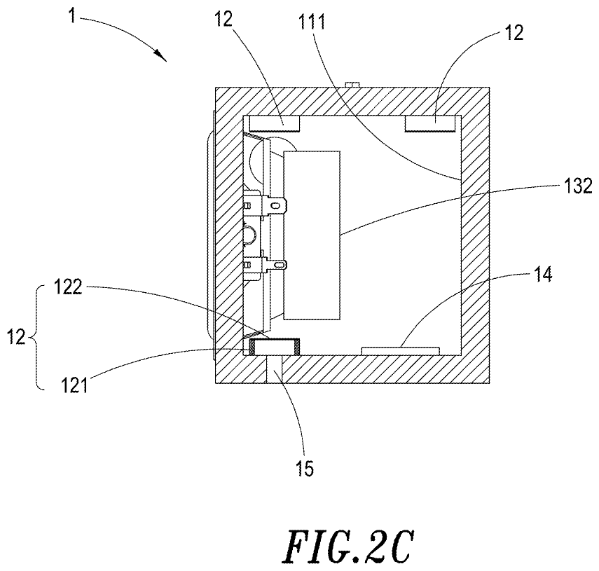

Moreover, as shown in FIGS. 2A-2C, the outer case 11 includes at least one through hole 15 which penetrates to the inner wall surface 111, and the diaphragm component 12 covers the through hole 15 on the inner wall surface 111.

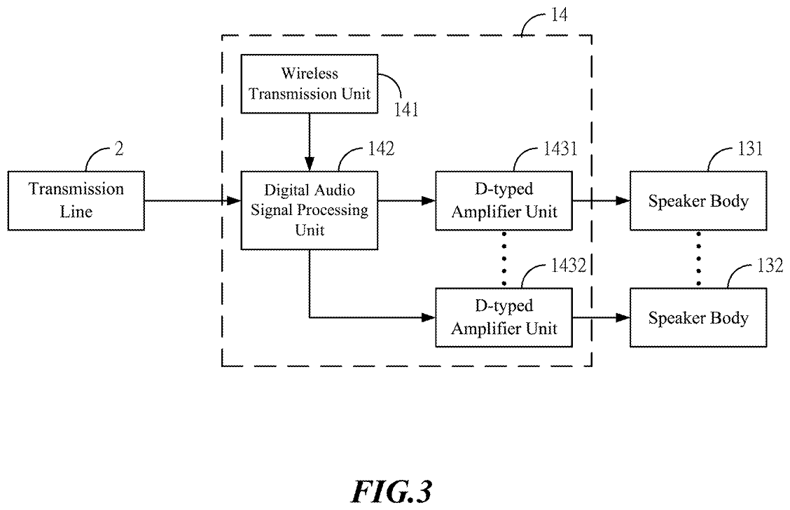

Besides, as shown in FIG. 3, the electric circuit board 14 includes a wireless transmission unit 141, a digital audio signal processing unit 142 and at least two D-typed amplifier units 1431, 1432, wherein the wireless transmission unit 141 receives an input audio by way of wireless transmissions (e.g., Bluetooth™ or Wi-Fi), and the digital audio signal processing unit 142 performs signal processes on the received input audio to generate the virtual sound field signal.

Also, each of the D-typed amplifier units 1431, 1432 can be correspondingly connected to one or more speaker bodies 131, 132. The D-typed amplifier unit is configured to receive the generated virtual sound field signal and convert to an output audio, and can then multiply the output audio in order to drive the speaker body corresponding to different sound channels for playing different channels. It can be appreciated that, since each of the D-typed amplifier units 1431, 1432 can output more than two channels and join the left and right channel outputs in parallel in order to provide a single channel output to a single or more than one speaker bodies 131, 132, the issue “the higher the power is, the larger the magnification becomes, but the increased signal distortion ratio will also occur” typically found in the D-typed amplifier units can be reduced, and the effect of acoustic perception efficiency multiplication can be achieved at the same time.

Furthermore, as shown in FIG. 3, the input audio can be sent into the one-to-many wireless speaker sound box device 1 via at least one transmission line 5, and the one-to-many wireless speaker sound box device 1 can be also configured with a USB interface for connecting the transmission line 5, or otherwise a flash drive, for example.

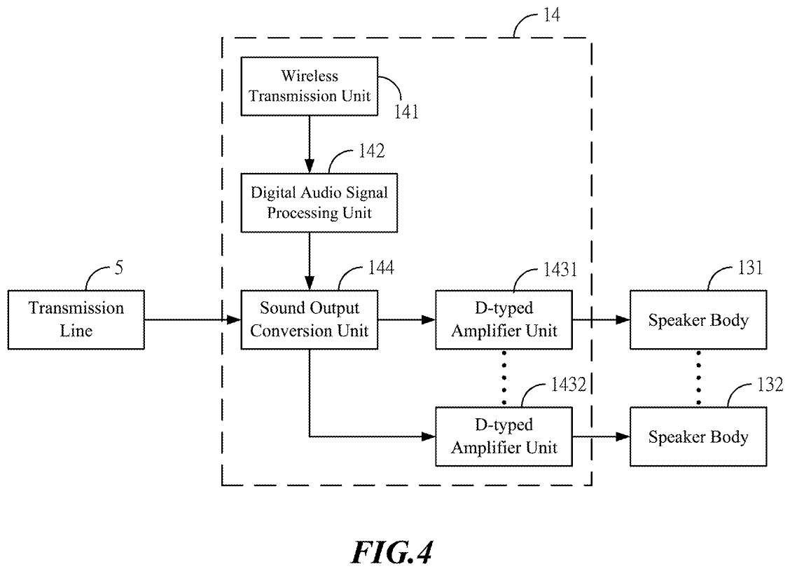

Also, the digital audio signal processing unit 142 can perform signal processes on the input audio signal so as to generate the virtual sound field signal of multiple sound channels. But, it should be understood that, in addition to the above-said architecture, other approaches or methods may be utilized as well; for example, as shown in FIG. 4, a sound output conversion unit 144 can be further connected between the digital audio signal processing unit 142 and the D-typed amplifier units 1431, 1432 in order to receive the virtual sound field signal and convert into the virtual sound field signal of multiple sound channels.

Moreover, in addition to being applied to play music as a single one-to-many wireless speaker sound box device, it is further possible to connect two or more one-to-many wireless speaker sound box devices in groups for playing/receiving audio signals in order to generate the intended multi-channel playback effect. Herein the so-called “multi-channel” can be of 2.0 channels, 2.1 channels, 5.1 channels, or 5.1 channels or more.

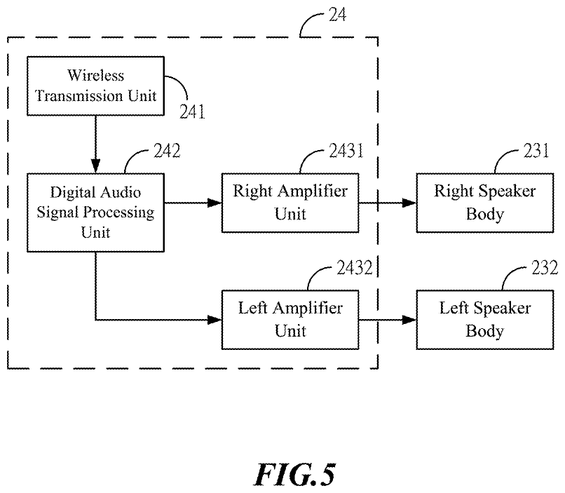

For example, upon using the architecture of the present invention on the one-to-many wireless speaker sound box device of 2.0 channels, as shown in FIG. 5, the illustrated one-to-many wireless speaker sound box device may comprise a right speaker body 231, a left speaker body 232 and an electric circuit board 24, wherein the electric circuit board 24 includes a wireless transmission unit 241, a digital audio signal processing unit 242, a right amplifier unit 2431, a left amplifier unit 2432 (herein both the right amplifier unit 2431 and the left amplifier unit 2432 are the D-typed amplifier units), and the digital audio signal processing unit 242 can convert and generate the virtual sound field signal of 2 sound channels which can be then respectively transferred to the right amplifier unit 2431 and the left amplifier unit 2432 thereby that the right amplifier unit 2431 drives the right speaker body 231 and the left amplifier unit 2432 drives the left speaker body 232 in operation.

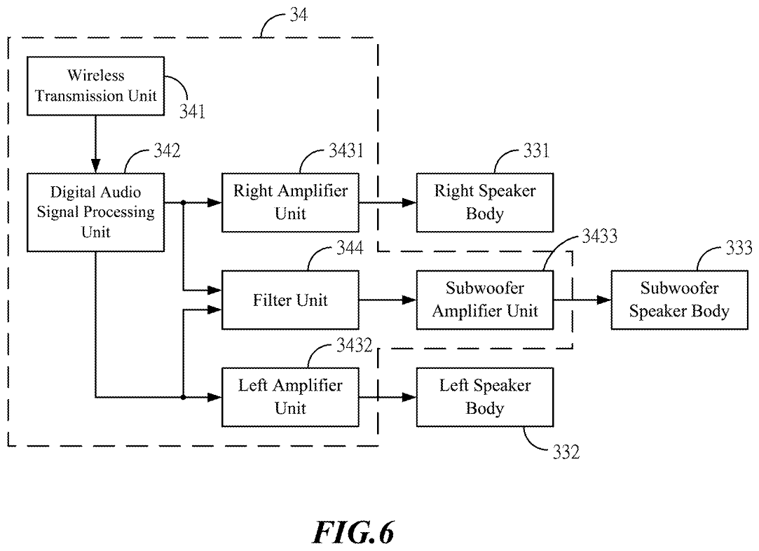

For another example, upon using the architecture of the present invention on the one-to-many wireless speaker sound box device of 2.1 channels, as shown in FIG. 6, the illustrated one-to-many wireless speaker sound box device may comprise a right speaker body 331, a left speaker body 332, a subwoofer speaker body 333 and an electric circuit board 34, wherein the electric circuit board 34 includes a wireless transmission unit 341, a digital audio signal processing unit 342, a right amplifier unit 3431, a left amplifier unit 3432, a subwoofer amplifier unit 3433 and a filter unit 344 (herein all the right amplifier unit 3431, the subwoofer amplifier unit 3433 and the left amplifier unit 3432 are the D-typed amplifier units), and the digital audio signal processing unit 342 can convert and generate the virtual sound field signal of 3 sound channels which can be then respectively transferred to the right amplifier unit 3431, the subwoofer amplifier unit 3433 and the left amplifier unit 3432 thereby that the right amplifier unit 3431 drives the right speaker body 331, the subwoofer amplifier unit 3433 drives the subwoofer speaker body 333 and the left amplifier unit 3432 drives the left speaker body 332 in operation.

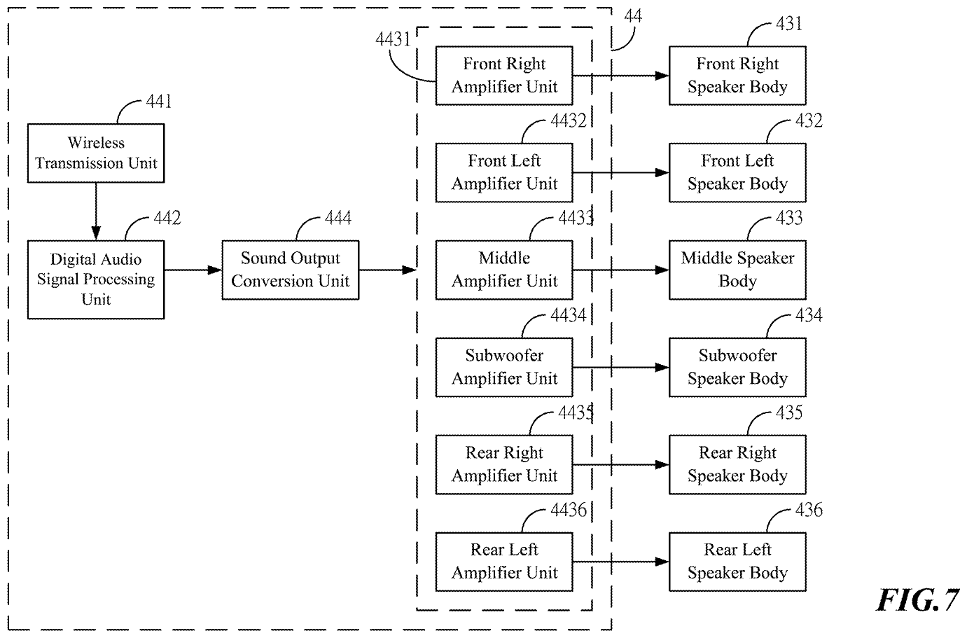

Additionally, for yet another example, upon using the architecture of the present invention on the one-to-many wireless speaker sound box device of 5.1 channels, as shown in FIG. 7, the illustrated one-to-many wireless speaker sound box device may comprise plural speaker bodies (i.e., a front right speaker body 431, a front left speaker body 432, a middle speaker body 433, a subwoofer speaker body 434, a rear right speaker body 435 and a rear left speaker body 436) and an electric circuit board 44, wherein the electric circuit board 44 includes a wireless transmission unit 441, a digital audio signal processing unit 442, a sound output conversion unit 444 and plural D-typed amplifier units (i.e., a front right amplifier unit 4431, a front left amplifier unit 4432, a middle amplifier unit 4433, a subwoofer amplifier unit 4434, a rear right amplifier unit 4435 and a rear left amplifier unit 4436), and the sound output conversion unit 444 can receive the virtual sound field signal generated by the digital audio signal processing unit 442 and convert to the virtual sound field signal of 6 sound channels which can be then respectively transferred to each of the different D-typed amplifier units to drive each of the different speaker bodies in operation.

In comparison with other conventional technologies, the one-to-many wireless speaker sound box device according to the present invention provides the following advantages:

(1) The present invention allows to use a single D-typed amplifier unit to drive only a single channel output or else more than one speaker bodies, thereby resolving the issue of excessively large signal distortion possibly occurring in such speaker bodies.

(2) The present invention has the advantages of high efficiency and low costs provided by the D-typed amplifier, and the defects of high distortion ratio and high signal-to-noise ratio commonly found in the D-typed amplifiers can be significantly improved, such that it can be applied to offer high acoustic quality and great listening perception effects.

It should be noticed that, although the present invention has been disclosed through the detailed descriptions of the aforementioned embodiments, such illustrations are by no means used to restrict the scope of the present invention; that is, skilled ones in relevant fields of the present invention can certainly devise any applicable alterations and modifications after having comprehended the aforementioned technical characteristics and embodiments of the present invention within the spirit and scope thereof. Hence, the scope of the present invention to be protected under patent laws should be delineated in accordance with the claims set forth hereunder in the present specification.

What is claimed is:

1. A one-to-many wireless speaker sound box device, comprising:
an outer case, including multiple inner wall surfaces which together form an accommodation space;
one or more diaphragm components which include an outer support frame and a diaphragm body, wherein the diaphragm body is bonded to one side of the outer support frame, and the other side of the outer support frame is fixed to the Inner wall surfaces;
at least two speaker bodies, which are disposed in the accommodation space, with each speaker body being used to play sounds of different channels; and
at least one electric circuit board, which is electrically connected to the speaker body and disposed in the accommodation space, in which the electric circuit board thereon includes:
a wireless transmission unit, used for receiving an input audio in a wireless transmission manner;
a digital audio signal processing unit, electrically connected to the wireless transmission unit for performing signal processing on the input audio in order to generate a virtual sound field signal; and
at least two or more D-typed amplifier units, electrically connected to the sound output conversion unit, with each D-typed amplifier unit being connected to one or more speaker bodies in correspondence with a single channel respectively, thereby receiving the virtual sound field signal through each D-typed amplifier unit and converting to obtain an output audio which is then amplified in multiple times so as to drive a single channel and one or more speaker body outputs, thus creating the multi-channel playback effect.

2. The one-to-many wireless speaker sound box device according to claim 1, wherein the wireless transmission mode of the wireless transmission unit is Bluetooth™ or Wi-Fi.

3. The one-to-many wireless speaker sound box device according to claim 1, which is integrally manufactured in one piece.

4. The one-to-many wireless speaker sound box device according to claim 1, wherein the multi-channel can be of 2.0 channels, 2.1 channels, 5.1 channels, or 5.1 channels or more.

5. The one-to-many wireless speaker sound box device according to claim 1, it is further possible to transfer the input audio signals into the one-to-many wireless speaker sound box device by way of at least one transmission line.

6. The one-to-many wireless speaker sound box device according to claim 1, wherein a sound output conversion unit is further connected between the digital audio signal processing unit and the D-typed amplifier unit in order to receive the virtual sound field signal and convert into the virtual sound field signal of multiple sound channels.

7. The one-to-many wireless speaker sound box device according to claim 1, wherein the digital audio signal processing unit performs signal processes on the input audio signal so as to generate the virtual sound field signal of multiple sound channels.

8. The one-to-many wireless speaker sound box device according to claim 1, wherein each of the D-typed amplifier units is able to output two or more sound channels, and to combine the left and right sound channel outputs in parallel into a single sound channel output.

9. The one-to-many wireless speaker sound box device according to claim 1, wherein, in addition to being applied to play/receive music as a single one-to-many wireless speaker sound box device, it is further possible to connect two or more one-to-many wireless speaker sound box devices in groups to play/receive audio signals in order to generate the effects of music playing and karaoke singing.

10. The one-to-many wireless speaker sound box device according to claim 1, wherein the issue “the higher the power is, the larger the magnification becomes, but the increased signal distortion ratio will also occur” typically found in the D-typed amplifier units can be resolved, and the effect of acoustic perception efficiency multiplication can be achieved.

11. The one-to-many wireless speaker sound box device according to claim 1, wherein the diaphragm body is made of soft or elastic materials, and able to replace any effects generated by conventional passive monomers or the sound tubes and reduce the external size and internal volume of the sound box.

12. The one-to-many wireless speaker sound box device according to claim 1, wherein the outer case includes at least one through hole which penetrates to the inner wall surface, and the diaphragm component covers the through hole on the inner wall surface.
